(19) United States
(12) Patent Application Publication
(10) Pub. No.: US 2024/0412951 A1
(43) Pub. Date: Dec. 12, 2024

(54) APPARATUS FOR TREATING SUBSTRATE AND METHOD FOR TREATING SUBSTRATE

(71) Applicant: SEMES CO., LTD., Cheonan-si (KR)

(72) Inventors: DONG-HUN KIM, Seoul (KR); WAN JAE PARK, Hwaseong-si (KR); SEONG GIL LEE, Hwaseong-si (KR); JI-HWAN LEE, Suwon-si (KR); YOUNGJE UM, Busan (KR); DONG SUB OH, Busan (KR); MYOUNGSUB NOH, Seoul (KR)

(73) Assignee: SEMES CO., LTD., Cheonan-si (KR)

(21) Appl. No.: 18/809,588

(22) Filed: Aug. 20, 2024

Related U.S. Application Data
(63) Continuation of application No. 17/202,244, filed on Mar. 15, 2021.

(30) Foreign Application Priority Data
Mar. 16, 2020 (KR) 10-2020-0032231

(51) Int. Cl. H01J 37/32

(52) U.S. Cl. CPC H01J 37/3244; H01J 37/32357; H01J 37/32422; H01J 37/32568; H01J 37/32715; H01J 37/32834; H01J 37/32091; H01J 37/32183; H01J 2237/334; H01J 2237/335

(57) ABSTRACT

An apparatus for treating a substrate includes a process chamber having an inner space, a support unit supporting a substrate in the inner space, a processing gas supply unit for supplying a processing gas to the inner space, and a plasma source that excites the processing gas in a plasma state in the inner space. The processing gas supply unit includes a heater that heats the processing gas.

### CROSS-REFERENCE TO RELATED APPLICATION

This application is a continuation of U.S. patent application Ser. No. 17/202,244 filed on Mar. 15, 2021, which claims priority under 35 U.S.C. § 119 to Korean Patent Application No. 10-2020-0032231 filed on Mar. 16, 2020, in the Korean Intellectual Property Office, the entire contents of each of which are hereby incorporated by reference.

### FIELD OF THE INVENTION

The present disclosure relates to an apparatus for treating substrate and method for treating substrate.

### BACKGROUND

Plasma may be used in the treating of a substrate. For example, plasma may be used in dry cleaning, ashing, or etching process. Plasma may be using very high temperature heat, strong electric fields or RF electromagnetic fields. And, plasma refers to an ionized gas composed of ions, electrons, radicals, or the like.

Dry cleaning, ashing, or etching using plasma are carried out by colliding ions or radical species included in the plasma with a substrate.

In case of a method using very high temperatures to generate plasma, excessive power is required to maintain such high temperature compared with when using an electric or electromagnetic field. Furthermore, there are the following problems: As the generated plasma moves along a supply line, residual plasma may be supplied to the downstream side of a valve in the supply line even after the valve is closed; As it takes several seconds to open and close the valve, TTTM (Tool to Tool Matching) may be difficult in the process which requires precise etching time.

In the case of a method using electric fields or electromagnetic fields, it only takes several tens of microseconds, which is shorter than that of the opening and closing the valve, to control supply and cut-off of power, thereby allowing for precise etching control. But compared with a pyrolysis method using very high temperatures, ions accelerated by the electric or electromagnetic field energy cause damage to electrodes, showerheads, insulators, etc., generating particles. Unfortunately, the greater is power to generate the electric or electromagnetic field, the greater is the damage, resulting in a large amount of particles, as well as shortening the lifespan of parts, which results in shorter replacement cycles.

### SUMMARY

The present disclosure is directed to providing an apparatus and a method capable of increasing substrate treating efficiency.

The present disclosure is also directed to providing an apparatus and a method capable of reducing damage to electrodes, showerheads, insulators, etc. while minimizing the required time to control plasma supply and interruption.

The purpose of the present disclosure is not limited thereto, and other purposes that are not mentioned will be clearly understood by those skilled in the art from the following description.

An exemplary embodiment of the present disclosure provides an apparatus for treating a substrate. In one embodiment, a substrate treating apparatus comprises: a process chamber having an inner space; a support unit supporting a substrate in the inner space; a processing gas supply unit for supplying a processing gas to the inner space; a plasma source that excites the processing gas in a plasma state in the inner space, wherein the processing gas supply unit includes a heater that heats the processing gas.

In one embodiment, a substrate treating apparatus further includes a control unit for controlling the heater, wherein the control unit may control the heater thereby, heating the processing gas to a pre-pyrolysis temperature of the processing gas.

In one embodiment, the processing gas supply unit further includes a gas supply line connected to the process chamber to supply the processing gas to the inner space, wherein the heater may be provided to the gas supply line.

In one embodiment, the gas supply line comprises: a first supply line for supplying the processing gas to a first area of the inner space; a second supply line for supplying the processing gas to a second area of the inner space. The heater comprises: a first heater provided in the first supply line; a second heater provided in the second supply line. The control unit may independently control the first heater and the second heater.

In one embodiment, the control unit may control the first heater and the second heater so that the temperature of the processing gas supplied to the first area through the first supply line is different from that of the processing gas supplied to the second area through the second supply line.

In one embodiment, the first area may be corresponding to a central zone of a substrate disposed on the support unit, and the second area may be corresponding to an edge zone of a substrate disposed on the support unit.

In one embodiment, a substrate treating apparatus may further include a showerhead that partitions the inner space into a plasma generation space for generating plasma and a processing space for treating a substrate and has a plurality of through-holes through which a plasma generated in the plasma generation space flows into the processing space.

In one embodiment, the showerhead may be connected to ground.

In one embodiment, a substrate treating apparatus further include an upper electrode to which high frequency power is applied over the showerhead that face each other at a distance. Further, a space between the upper electrode and the showerhead may be provided as the plasma generation space.

In another aspect of an embodiment of the present disclosure, an apparatus for treating a substrate comprises: a process chamber having a processing space; a support unit supporting a substrate in the processing space; an exhaust unit for exhausting gas inside of the processing space; a plasma chamber providing a plasma generation space, wherein the plasma chamber is provided in the upstream of the process chamber; a first processing gas supply unit that supplies a first processing gas to the plasma chamber; a plasma source that excites the first processing gas supplied to the plasma chamber in a plasma state, and the processing gas supply unit includes a heater that heats the first processing gas.

In one embodiment, the first processing gas may include a fluorine-containing gas.

In one embodiment, a control unit for controlling the heater is further included, wherein the control unit may control the heater to heat the first processing gas to the pre-pyrolysis temperature of the first processing gas.

In one embodiment, an ion blocker is provided between the plasma chamber and the process chamber, wherein the ion blocker may be connected to ground.

In one embodiment, the processing space may further include a second processing gas supply unit that supplies a second processing gas.

In one embodiment, the first processing gas includes a fluorine-containing gas, and the second processing gas may include a hydrogen and nitrogen-containing gas.

In one embodiment, the first processing gas supply unit includes: a plurality of supply lines that each supplies the first processing gas to different areas of the plasma generation space, wherein the heater is provided in each of the supply lines.

In one embodiment, a control unit for controlling the heater is included, wherein the control unit may independently control the heater.

The present disclosure is directed to providing a method of treating a substrate. In one embodiment, the substrate treating method comprises: supplying a first processing gas to a plasma generation space to generate plasma from the first processing gas, and treating the substrate by supplying the plasma to the substrate, wherein the first processing gas is supplied to the plasma generation space after being heated.

In one embodiment, the first processing gas may be supplied to the plasma generation space after being heated to the pre-pyrolysis temperature.

In one embodiment, the first processing gas is supplied to different areas of the plasma generation space, and the temperature of the first processing gas supplied to one area may be different from the temperature of the first processing gas supplied to another area.

In one embodiment, the one area may correspond to a central zone of the substrate, and another area may correspond to an edge zone of the substrate.

In another aspect of an embodiment of the present disclosure, a method of treating a substrate comprises the steps of: heating a first processing gas; supplying the heated first processing gas to a plasma generation space and exciting the first processing gas into a plasma state by applying a high frequency to the plasma generation space; providing radicals after filtering ions from the plasma which is excited from the plasma generation space to a processing space provided with a substrate; obtaining a reactive gas after reacting the radicals with the second processing gas by supplying a second processing gas to the processing space; and treating the substrate with the reactive gas.

In one embodiment, the step of providing radicals after filtering ions from the plasma which is excited from the plasma generation space to a processing space provided with a substrate is performed by providing a showerhead having through holes formed between the plasma generation space and the processing space, wherein the showerhead may be connected to ground.

In one embodiment, the first processing gas may be heated to the pre-pyrolysis temperature.

In one embodiment, the substrate treating may remove a natural oxide layer of the substrate.

In one embodiment, the first processing gas may include a fluorine-containing gas.

In one embodiment, the second processing gas may include nitrogen and hydrogen-containing gas.

According to an exemplary embodiment of the present disclosure, substrate treating efficiency may increase.

According to an exemplary embodiment of the present disclosure, damage incurred to electrodes, showerheads, insulators, etc. may be reduced while the required time to control supply and interruption of plasma is minimized.

The effects of the present disclosure are not limited thereto, and other effects that are not mentioned will be clearly understood by those having an ordinary skill in the art from the present specification and the accompanying drawings.

### BRIEF DESCRIPTION OF THE FIGURES

FIG. 1 is a schematic cross-sectional view of a substrate treating apparatus according to a first embodiment of the present disclosure.

FIG. 2 is a view showing an operating state of the substrate treating apparatus according to the first embodiment of the present disclosure.

FIG. 3 is a schematic cross-sectional view of a substrate treating apparatus according to a second embodiment of the present disclosure, and is a view showing an operating state thereof.

FIG. 4 is a schematic cross-sectional view of a substrate treating apparatus according to a third embodiment of the present disclosure.

FIG. 5 is a plan view showing a supply area of a first processing gas provided to a substrate treating apparatus according to a third embodiment of the present disclosure.

FIG. 6 is a view showing an operation state of the substrate treating apparatus according to the third embodiment of the present disclosure.

FIG. 7 is a view showing another operating state of the substrate treating apparatus according to the third embodiment of the present disclosure.

FIG. 8 is a schematic cross-sectional view of a substrate treating apparatus according to a fourth embodiment of the present disclosure.

FIG. 9 is a schematic cross-sectional view of a substrate treating apparatus according to a fifth embodiment of the present disclosure.

FIG. 10 is a schematic cross-sectional view of a substrate treating apparatus according to a sixth embodiment of the present disclosure.

### DETAILED DESCRIPTION

Hereinafter, embodiments of the present disclosure will be described in more detail with reference to the accompanying drawings. The embodiments of the present disclosure may be modified in various forms, and the scope of the present disclosure should not be construed as being limited to the following embodiments. This embodiment is provided to more completely explain the present disclosure to those with average knowledge in the art. Therefore, the shape of the element in the drawings has been exaggerated to emphasize a clearer explanation.

As exemplary embodiments, a substrate treating apparatus for dry cleaning or etching a substrate using plasma in a chamber will be described. However, the present disclosure is not limited thereto, and any apparatus that processes a substrate using plasma can be applied to various processes.

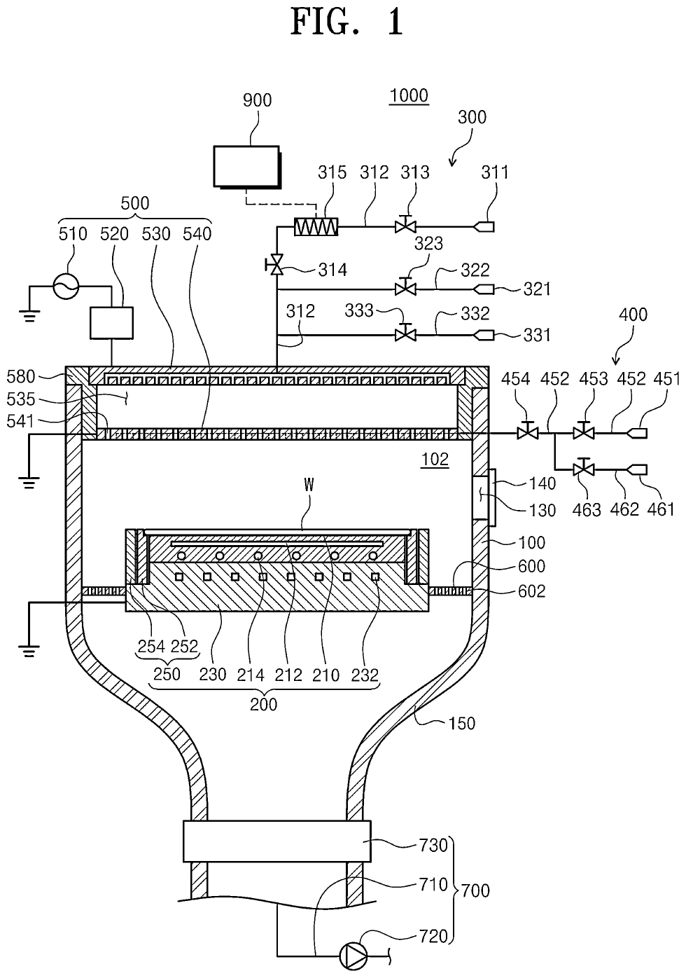

Hereinafter, an embodiment of the present disclosure will be described with reference to FIGS. 1 to 6.

FIG. 1 is a schematic cross-sectional view of a substrate treating apparatus according to a first embodiment of the present disclosure. Referring to FIG. 1, the substrate treating apparatus 1000 includes a process chamber 100, a support unit 200 (i.e., a substrate support unit), a first processing gas supply unit 300, a second processing gas supply unit 400, a plasma source 500, an exhaust baffle 600, and an exhaust unit 700.

The process chamber 100 has an inner space. In the inner space, a processing space 102 provides a space in which the substrate W is processed. The process chamber 100 is provided in an annular cylindrical shape. The process chamber 100 is made of a metal material. For example, the process chamber 100 may be made of aluminum. An opening 130 is formed in one side wall of the process chamber 100. The opening 130 is provided as an entrance through which the substrate W can be carried in and out. The opening 130 can be opened and closed by a door 140. An exhaust port 150 is installed at the bottom side of the process chamber 100. The exhaust port 150 is concentric to the central axis of the process chamber 100. The exhaust port 150 functions as an outlet through which by-products generated in the processing space 102 are discharged to the outside of the process chamber 100.

The support unit 200 is provided in the processing space 102 to support the substrate W. The support unit 200 may be provided as an electrostatic chuck that supports the substrate W using electrostatic force.

In one embodiment, the support unit 200 includes a dielectric plate 210, a focus ring 250 and a base 230. The substrate W is directly disposed on the upper surface of the dielectric plate 210. The dielectric plate 210 is provided in a disk shape. The dielectric plate 210 may have a radius smaller than that of the substrate W. An internal electrode 212 is installed inside the dielectric plate 210.

The internal electrode 212 is connected to a power source (not shown) and receives power from the power source (not shown). The internal electrode 212 provides electrostatic force from the applied power so that the substrate W is adsorbed to the dielectric plate 210. A heater 214 for heating the substrate W is installed inside the dielectric plate 210. The heater 214 may be located under the internal electrode 212. The heater 214 may be provided as a spiral coil. For example, the dielectric plate 210 may be made of a ceramic material.

The base 230 supports the dielectric plate 210. The base 230 is located under the dielectric plate 210 and is fixedly coupled to the dielectric plate 210. The upper surface of the base 230 has a stepped shape such that the central zone is higher than the edge zone. The dielectric plate 210 aligns with the central zone of the base 230. The side surface of the central zone is flushed with the side surface of the dielectric plate 210. A cooling channel 232 is formed inside the base 230. The cooling channel 232 is provided as a passage through which cooling fluid circulates. The cooling channel 232 may be provided in a spiral shape inside the base 230. The base 230 may be electrically connected to ground. Alternatively, the base 230 may be connected to a high-frequency power source (not shown) located outside. The base 230 may be made of a metal material.

The focus ring 250 is provided to surround the peripheries of the dielectric plate 210 and the substrate W. The focus ring 250 concentrates the plasma onto the substrate W. In one embodiment, the focus ring 250 may include an inner ring 252 and an outer ring 254. The inner upper portion of the inner ring 252 is formed to be stepped, so that the edge of the substrate W may be disposed on the stepped portion. The focus ring 250, as a ring around an electrostatic chuck (ESC) on which a wafer is disposed, is manufactured of a material that particles are not caused by the etching process and made of silicon oxide film (SiO2), silicon single crystal or silicon fluoride film (SiF) etc. Furthermore, the focus ring 250 may be replaced when worn out.

A plasma source 500 may be provided as a capacitively coupled plasma source. The plasma source 500 includes a high frequency power source 510, an impedance matcher 520, an upper electrode 530, and a showerhead 540.

The upper electrode 530 and the showerhead 540 face each other at a distance, and the upper electrode 530 is disposed over the showerhead 540. A plasma generation space 535 is formed between the upper electrode 530 and the showerhead 540. The showerhead 540 partitions the internal space of the process chamber 100 into a processing space 102 and a plasma generation space 535. A sidewall ring 580 provided as an insulator is provided on the side of the plasma generation space 535. The upper electrode 530, the showerhead 540, and the sidewall ring 580 in combination form a plasma chamber defining the plasma generation space 535 therein. The plasma generation space 535 is connected to the first processing supply unit 300 supplying the first processing gas.

The first processing gas supply unit 300 includes a first gas supply source 311 and a first gas supply line 312, and the first gas supply line 312 is provided with flow controllers 313, 314 and a heater 315.

The first gas supply source 311 stores a first gas. The first gas is a fluorine-containing gas. In one embodiment, the first gas may be NF₃.

The first gas supply line 312 is provided as a fluid passage connecting the first gas supply source 311 and the process chamber 100. The first gas supply line 312 supplies the first gas stored in the first gas supply source 311 to the inner space of the process chamber 100. Specifically, the first gas supply line 312 supplies the first gas to the plasma generation space 535. The first processing gas supply unit 300 may further include a further gas supply source to be mixed with the first gas, for example, a second gas supply source 321 for supplying a second gas different from the first gas, and/or a third gas supply source 331 for supplying a third gas different from the first gas and the second. The second gas supply source 321 is connected to the first gas supply line 312 through the second gas supply line 322. The third gas supply source 331 is connected to the first gas supply line 312 through the third gas supply line 332. A flow controller 323 may be installed on the second gas supply line 322. A flow controller 333 may be installed on the third gas supply line 332. The second gas may be an inert gas. For example, the second gas may be argon (Ar). The third gas may be an inert gas of a different kind from the second gas. For example, the third gas may be helium (He).

The first processing gas may be defined by a combination of the first gas and one or more of the second gas and the third gas. Alternatively, the first gas alone may be defined as the first processing gas. Any additional gas may be further mixed with the first gas and/or the mixture of the first and/or the second and/or the third gas to define the first processing gas.

The heater 315 is provided on the first gas supply line 312. The heater 315 heats the first processing gas. The operation of the heater 315 may be controlled by the controller 900, and the controller 900 controls the heater 315 such that the heater 315 heats the first processing gas to a pre-pyrolysis temperature of the first processing gas. The pre-pyrolysis temperature of the first processing gas may vary depending on the kind of the first processing gas and the atmosphere in which the first processing gas is heated, such as a pressure in the supply line, but refers to a temperature (e.g., 20° C. to 100° C.) sufficiently lower than the pyrolysis temperature. For example, the pre-pyrolysis temperature of the first processing gas may refer to a temperature (e.g., 20° C.˜100° C.) lower than a temperature at which the pyrolysis begins to occur actively. In one embodiment, the controller 900 calculates the pyrolysis temperature of the first processing gas based on the kind of the first gas and the pressure of the first gas and controls the heater 315 to heat the first processing gas to a temperature sufficiently below the pyrolysis temperature. When the first processing gas is NF₃, the heater 315 heats the first processing gas (NF₃) to a temperature having a value from 500° C. to 580° C., which is lower than the pyrolysis temperature (e.g., 600° C.) of NF₃ by 20° C.˜100° C.

The heater 315 may be provided at an upstream or downstream side of the first gas supply line 312 to which the second gas supply line 322 or the third gas supply line 332 is connected. In this exemplary embodiment, the heater 315 is provided at upstream side of the to which the second gas supply line 322 or the third gas supply line 332 is connected.

A high frequency power source 510 is connected to the upper electrode 530. The high frequency power source 510 applies high frequency power to the upper electrode 530. An impedance matcher 520 is provided between the high frequency power source 510 and the upper electrode 530.

An electromagnetic field generated between the upper electrode 530 and the showerhead 540 excites the heated first processing gas introduced into the plasma generation space 535 into a plasma state. The heated first processing gas introduced into the plasma generation space 535 is converted to a plasma state. As the first processing gas is converted to the plasma state, it is decomposed into ions, electrons, and radicals. The generated radical species passes through the showerhead 540 and moves to the processing space 102.

The showerhead 540 is provided between the processing space 102 and the plasma generation space 535 and forms a boundary between the processing space 102 and the plasma generation space 535.

The showerhead 540 is made of a conductive material. The showerhead 540 is provided in a plate shape. For example, the showerhead 540 may have a disk shape. A plurality of through holes 541 are formed in the showerhead 540. The through holes 541 are oriented in the vertical direction of the showerhead 540.

The showerhead 540 is provided to be connected to ground. As the showerhead 540 is connected to ground, ions and electrons among plasma components passing through the showerhead 540 are drained to the ground. That is, the showerhead 540 functions as ion and/or electron blocker that blocks ions and/or electrons from passing through the through holes 541 to the processing space 102. As the showerhead 540 is connected to ground, only radicals among the plasma components pass through the through holes 541 to the processing space 102.

The second processing gas supply unit 400 for supplying a second processing gas is connected to the processing space 102. The second processing gas supply unit 400 includes a fourth gas supply source 451 and a fourth gas supply line 452. Flow controllers 453,454 are installed on the fourth gas supply line 452.

The fourth gas supply source 451 stores a fourth gas. The fourth gas is a nitrogen- or hydrogen-containing gas. In one embodiment, the fourth gas is NH₃.

The fourth gas supply line 452 is provided as a fluid passage connecting the fourth gas supply source 451 and the process chamber 100. The fourth gas supply line 452 supplies the fourth gas stored in the fourth gas supply source 451 to the inner space of the process chamber 100. Specifically, the fourth gas supply line 452 supplies the fourth gas to the processing space 102.

The second processing gas supply unit 400 may further include a fifth gas supply source 461 for supplying a fifth gas different from the fourth gas to supply further gas mixed with the fourth gas. The fifth gas supply source 461 is connected to the fourth gas supply source 451 through the fifth gas supply line 462. A flow controller 463 may be installed on the fifth gas supply line 462. The fifth gas is a nitrogen- or hydrogen-containing gas. For example, the fifth gas may be H₂.

The second processing gas may be defined by a combination of the fourth gas and the fifth gas. Alternatively, the fourth gas alone may be defined as the second processing gas. Any additional gas may be further mixed with the fourth gas and/or the mixture of the fourth and fifth gas to define the second processing gas.

The second processing gas introduced into the processing space 102 reacts with plasma generated from the first processing gas and introduced into the processing space 102 to generate a reactive gas. More specifically, the second processing gas reacts with radicals among plasma generated from the first processing gas and passes through the showerhead 540 in the processing space 102 to generate the reactive gas. In one embodiment, the radical is a fluorine radical (F*), the second processing gas is gas mixtures of NH₃ and H₂, and the reactive gas is ammonium hydrogen fluoride (NH₄FHF) and/or NH₄F (ammonium fluoride).

The reactive gas removes the natural oxide film from the substrate by reacting with the natural oxide film.

The exhaust baffle 600 uniformly exhausts plasma for each area in the processing space. The exhaust baffle 600 is located between the inner wall of the process chamber 100 and the support unit 200 in the processing space. The exhaust baffle 600 is provided in an annular ring shape. A plurality of through holes 602 are formed in the exhaust baffle 600. The through holes 602 are oriented in the vertical direction. The through holes 602 are arranged along the circumferential direction of the exhaust baffle 600. The through holes 602 may have a slit shape with its lengthwise direction being the radial direction of the exhaust baffle 600.

The exhaust unit 700 includes an exhaust line 710, an exhaust pump 720, and an on-off valve 730. In an embodiment, the exhaust unit 700 may further include an exhaust port 150 for exhausting process by-products, which is connected to the on-off value 730. The exhaust pump 720, the on-off valve 730, and the exhaust line 710 is installed at a downstream side of the exhaust baffle 600 of the process chamber 100.

The exhaust line 710 is installed in the exhaust port 150, and an exhaust pump 720 is installed on the exhaust line 710. The exhaust pump 720 provides vacuum pressure to the exhaust port 150. By-products generated during the process and the processing gas or reactive gas remaining in the process chamber 100 are discharged to the outside of the process chamber 100 by vacuum pressure. The on-off valve 730 controls the exhaust pressure provided from the exhaust pump 720. The on-off valve 730 opens and closes the exhaust port 150. The on-off valve 730 is movable to an open position and a shut-off position. The open position herein is a position at which the exhaust port 150 is opened by the on-off valve 730, and the shut-off position is a position at which the exhaust port 150 is blocked by the on-off valve 730. The on-off valve 730 may include independently controllable a plurality of valves arranged for each zone of a plane perpendicular to the longitudinal direction of the exhaust port 150. The plurality of valves of the on-off valve 730 may be independently controlled by a valve controller (not shown). According to one embodiment, some zones of the exhaust port 150 may be provided to be open by open the valve(s) arranged therein during the process. The opening zone of the exhaust port 150 may be provided as an asymmetric manner. When viewed from above, this asymmetric opening area may be provided corresponding to only some of the divided areas.

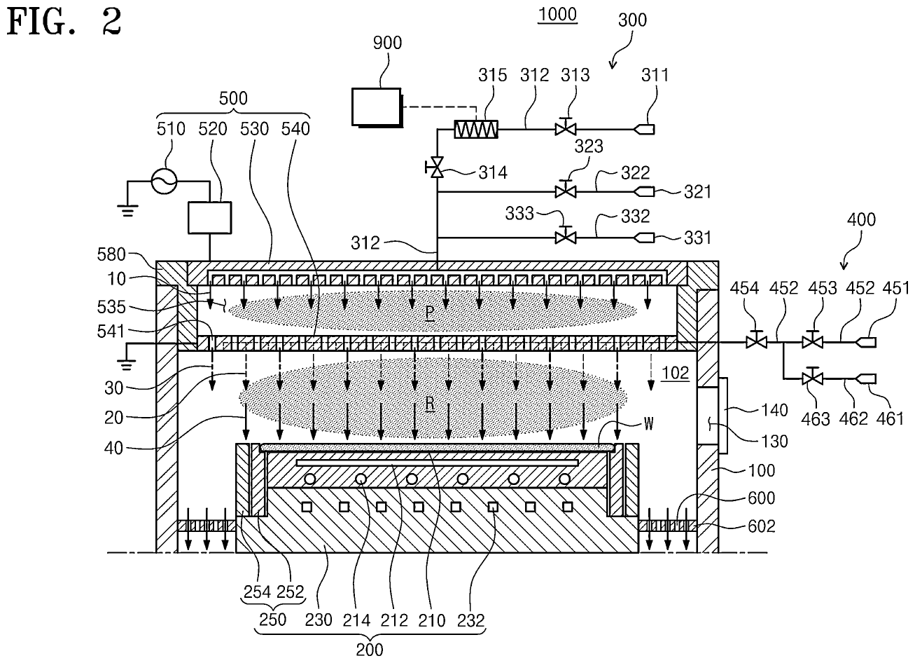

FIG. 2 is a view illustrating an operating state of the substrate treating apparatus according to the first embodiment of the present disclosure.

The first processing gas 10 is uniformly supplied to the plasma generation space 535, and the first processing gas 10 is excited in a plasma P state in the plasma generation space 535. Ions and electrons among the components of the plasma P are drained to the grounded showerhead 540 functioning as an ion blocker, and the radicals 30 flow into the processing space 102 by passing through the through holes 541. The radicals 30 forms a reactive gas 40 by reacting with the second processing gas 20 supplied to the processing space 102 and the reactive gas 40 processes the substrate W.

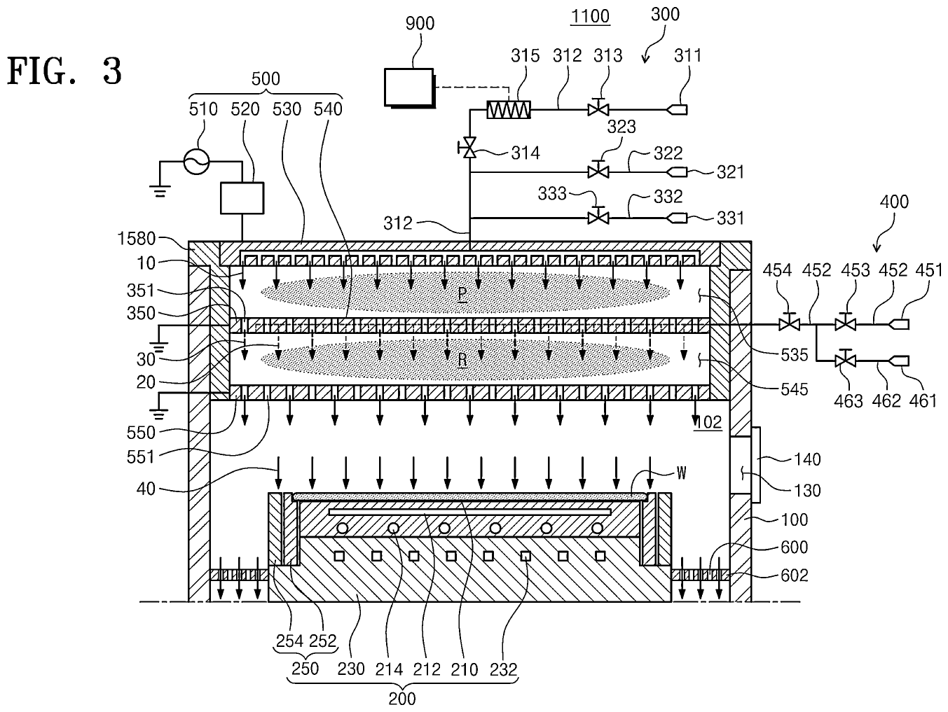

FIG. 3 is a schematic cross-sectional view of the substrate treating apparatus 1100 according to the second embodiment of the present disclosure, and is a view illustrating an operating state thereof. Hereinafter, a configuration in the second embodiment can be implemented in a similar manner to the case of the first embodiment by replacing the configurations of the second embodiment with the configurations of the first embodiment that correspond to those of the second embodiment as mentioned above. In this case, the same drawing references are used in the similar manner to the case of the first embodiment.

The substrate treating apparatus 1100 according to the second embodiment further includes a lower showerhead 550.

The lower showerhead 550 has a plate shape. For example, the lower showerhead 550 may have a disk shape. The lower showerhead 550 is arranged below the showerhead 540. A reaction space 545 (i.e., a reactive gas generation space) is formed between the lower showerhead 550 and the showerhead 540. Sidewall rings 1580 provided as insulators are provided on the sides of the plasma generation space 535 and the reaction space 545. The upper electrode 530, the showerhead 540, and the sidewall ring 1580 in combinations form a plasma chamber defining a plasma generation space 535 therein. And the showerhead 540, the lower showerhead 550 and the sidewall rings 1580 in combinations forma reactive gas generation chamber defining the reaction space 545 therein.

The second processing gas supply unit 400 supplies the second processing gas to the reactive gas generation space 545. In the reactive gas generation space 545, radicals generated from the first processing gas forms a reactive gas by reacting with the second processing gas. In one embodiment, the radicals passing through the showerhead 540 among plasma generated from the first processing gas forms a reactive gas by reacting with the second processing gas in the reactive gas generation space 545.

The bottom of the lower showerhead 550 is exposed to the processing space 102. A plurality of distribution holes 551 are formed in the lower showerhead 550. Each distribution hole 551 is oriented in the vertical direction of the lower showerhead 550. The reactive gas is supplied to the processing space 102 through the distribution holes 551. For example, the lower showerhead 550 is made of a conductive material and is grounded. The lower showerhead 550 discharges the reactive gas into the processing space 102. The lower showerhead 550 is disposed over the support unit 200. The lower showerhead 550 is oriented to face the dielectric plate 210. The reactive gas that has passed through the lower showerhead 550 is uniformly supplied to the processing space 102 to process the substrate.

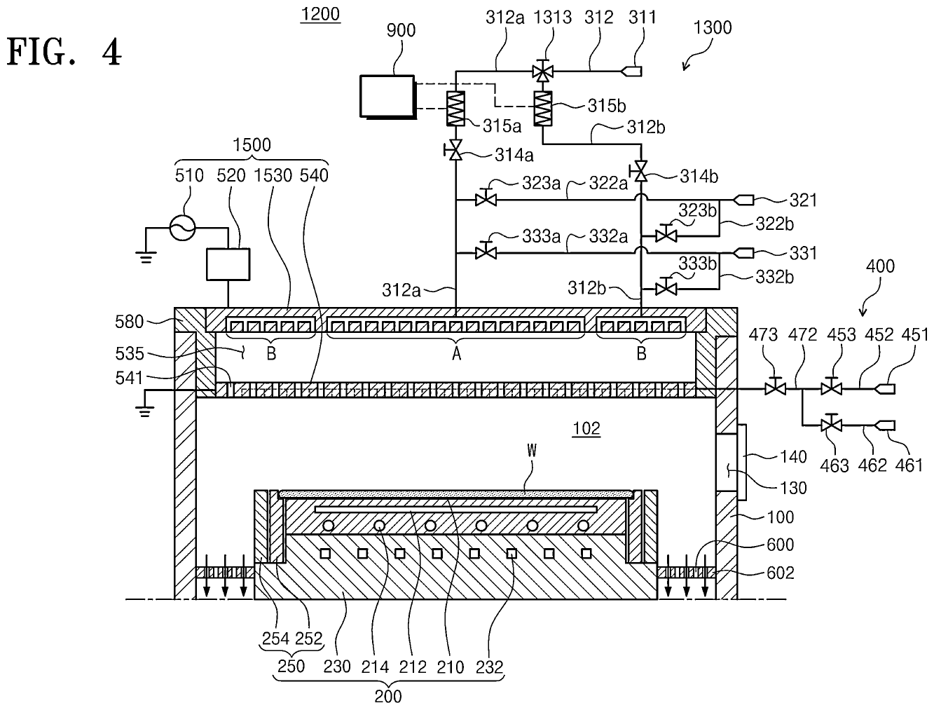

FIG. 4 is a schematic cross-sectional view of a substrate treating apparatus 1200 according to a third embodiment of the present disclosure. Hereinafter, a configuration in the third embodiment can be implemented in a similar manner to the case of the first embodiment by replacing the configurations of the third embodiment with the configurations of the first embodiment that correspond to those of the third embodiment as mentioned above. In this case, the same drawing references are used in the similar manner to the case of the first embodiment.

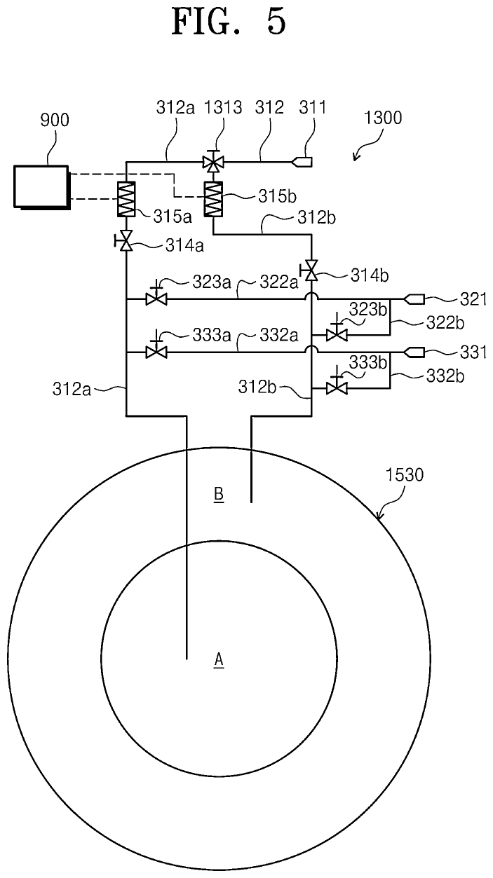

The first processing gas supply unit 1300 may supply the first processing gas to the plasma generation space 535 via different routes (e.g., via a first supply line 312a (i.e., a first gas supply line) and a second supply line 312b (i.e., a second gas supply line)) to different areas of the plasma generation space 535. FIG. 5 is a plan view illustrating the first processing gas supply area provided to the substrate treating apparatus 1200 according to the third embodiment of the present disclosure through the upper electrode 1530. Referring further to FIG. 4 in combination with FIG. 5, in this embodiment of the present disclosure, the upper electrode 1530 may function as a distributor that uniformly distributes the first processing gas. The first processing gas may be distributed to a pre-set area through the upper electrode 1530. The plasma generation space 535 is provided with a first area A and a second area B. The first area A corresponds to the central zone of the substrate W disposed on the support unit 200, and the second area B corresponds to the edge zone of the substrate W disposed on the support unit 200.

The first processing gas supply unit 1300 includes a first supply line 312a that supplies the first processing gas to the first area A and a second supply line 312b that supplies the first processing gas to the second area B. The first supply line 312a and the second supply line 312b may be branched from the first gas supply line 312. Although not shown, the first supply line and the second supply line may be directly connected to the first gas supply source 311, respectively. The first processing gas supply unit 1300 may further include a second gas supply source 321 for supplying a second gas different from the first gas, and/or a third gas supply source 331 for supplying a third gas different from the first gas and the second gas in order to form gas mixtures with the first gas. The second gas supply source 321 is connected to the first supply line 312a through a third supply line 322a (i.e., a third gas supply line). In addition, the second gas supply source 321 is connected to the second supply line 312b through a fourth supply line 322b. The third gas supply source 331 is connected to the first supply line 312a through a fifth supply line 332a. In addition, the third gas supply source 331 is connected to the second supply line 312b through a sixth supply line 332b. A flow controller 323a may be installed on the third supply line 322a. A flow controller 323b may be installed on the fourth supply line 322b. A flow controller 333a may be installed on the fifth supply line 332a. A flow controller 333b may be installed on the sixth supply line 332b. The second gas may be an inert gas. For example, the second gas may be argon (Ar). The third gas may be an inert gas of a different kind from the second gas. For example, the third gas may be helium (He).

The first processing gas may be defined by a combination of the first gas and one or more of the second gas and the third gas. Alternatively, the first gas alone may be defined as the first processing gas. The first processing gas may be gas mixtures in which an additional gas is mixed in addition to the illustrated embodiment.

Heaters are provided on each of the first supply line 312a and the second supply line 312b. A heater provided on the first supply line 312a is a first heater 315a, and a heater provided to the second supply line 312b is a second heater 315b. The first heater 315a heats the first processing gas supplied to the first area A. The second heater 315b heats the first processing gas supplied to the second area B. The operations of the first heater 315a and the second heater 315b may be independently controlled by the controller 900. The controller 900 controls one or more of the first heater 315a and the second heater 315b, such that the first processing gas is heated to a pre-pyrolysis temperature of the first processing gas. The pre-pyrolysis temperature of the first processing gas may vary depending on the kind of the first processing gas and the atmosphere in which the first processing gas is heated, such as a pressure in the supply line, but refers to a temperature (e.g., 20° C. to 100° C.) sufficiently lower than the pyrolysis temperature. For example, the pre-pyrolysis temperature of the first processing gas may refer to a temperature (e.g., 20° C. to 100° C.) lower than a temperature at which the pyrolysis begins to occur actively. In one embodiment, the controller 900 calculates the pyrolysis temperature of the first processing gas by reading the pressure of the first supply line 312a from the first heater 315a and the pressure of the second supply line 312b from the second heater 315b respectively and heats the first processing gas to a temperature sufficiently below the pyrolysis temperature.

The first heater 315a may be provided upstream or downstream of the first supply line 312a to which either the third supply line 322a or the fifth supply line 332a is connected. The second heater 315b may be provided upstream or downstream of the second supply line 312b to which the fourth supply line 322b or the sixth supply line 332b is connected. In this exemplary embodiment, the first heater 315a is provided at upstream side of the third supply line 322a and the fifth supply line 332a in the first supply line 312a, and the second heater 315b is provided upstream of the fourth supply line 322b and the sixth supply line 332b in the second heater 315b.

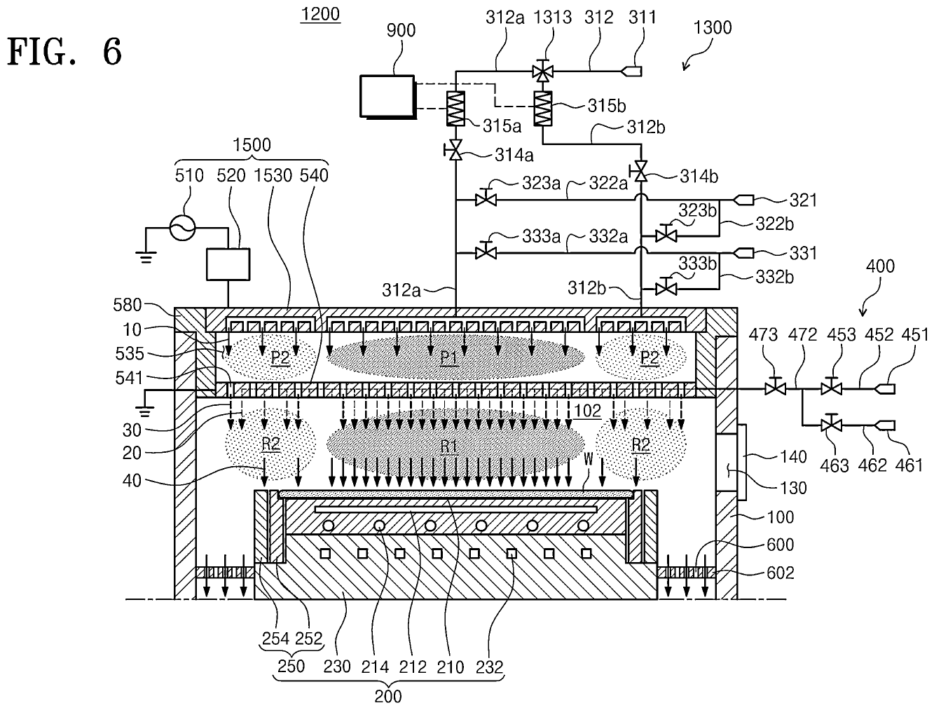

FIG. 6 is a view illustrating an operating state of the substrate treating apparatus according to the third embodiment of the present disclosure. Hereinafter, an operation of a substrate treating apparatus according to a third embodiment of the present disclosure will be described with reference to FIG. 6.

Controller 900 sets the temperature of the first processing gas supplied to the first area A higher than that of the first processing gas supplied to the second area B by controlling the first heater 315a and the second heater 315b. For example, the pyrolysis temperature of NF₃ is 600° C. If the first processing gas is NF₃, the first heater 315a is controlled to heat the first processing gas supplied to the first area A to a temperature having a value from 500° C. to 550° C., and the second heater 315b is controlled to heat the first processing gas supplied to the second area B to a temperature having a value from 550° C. to 580° C. When the temperature of the first processing gas supplied to the first area A is higher than that of the first processing gas supplied to the second area B, the density of the plasma P1 generated in the first area A is higher than that of the plasma P2 generated in the second area. Since the amount of radicals supplied to the processing space 102 corresponding to the first area A is greater than that of radicals supplied to the processing space 102 corresponding to the second area B, the amount of the reactive gas R1 generated in the processing space 102 corresponding to the first area A is more than that R2 of reactive gas generated in the processing space 102 corresponding to the second area B. Accordingly, the amount of the reactive gas supplied to the central zone of the substrate W corresponding to the first area A is greater than that of the reactive gas supplied to the edge zone of the substrate W corresponding to the second area B. In addition, the treating degree of each area of the substrate W may be different.

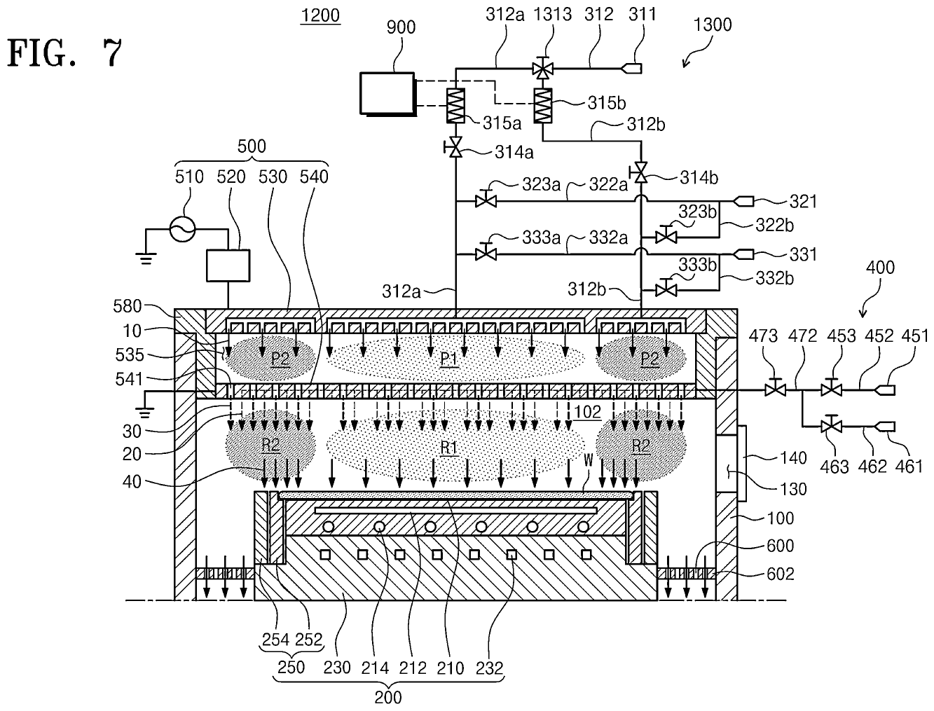

FIG. 7 is a view illustrating another operating state of the substrate treating apparatus according to the third embodiment of the present disclosure.

The controller 900 sets the temperature of the first processing gas supplied to the first area A lower than that of the first processing gas supplied to the second area B by controlling the first heater 315a and the second heater 315b. For example, if the first processing gas is NF₃, the first heater 315a is controlled to heat the first processing gas supplied to the first area A to a temperature having a value from 500° C. to 550° C. and the second heater 315b is controlled to heat the first processing gas supplied to the first area B to a temperature having a value from 550° C. to 580° C. When the temperature of the first processing gas supplied to the first area A is lower than that of the first processing gas supplied to the second area B, the density of the plasma P1 generated in the first area A is lower than that of the plasma P2 generated in the second area. Since the amount of radicals supplied to the processing space 102 corresponding to the first area A is fewer than that of radicals supplied to the processing space 102 corresponding to the second area B, the amount of the reactive gas R1 generated in the processing space 102 corresponding to the first area A is less than that R2 of reactive gas generated in the processing space 102 corresponding to the second area B. Accordingly, the amount of the reactive gas supplied to the central zone of the substrate W corresponding to the first area A is fewer than that of the reactive gas supplied to the edge zone of the substrate W corresponding to the second area B. In addition, the treating degree of each area of the substrate W may be different.

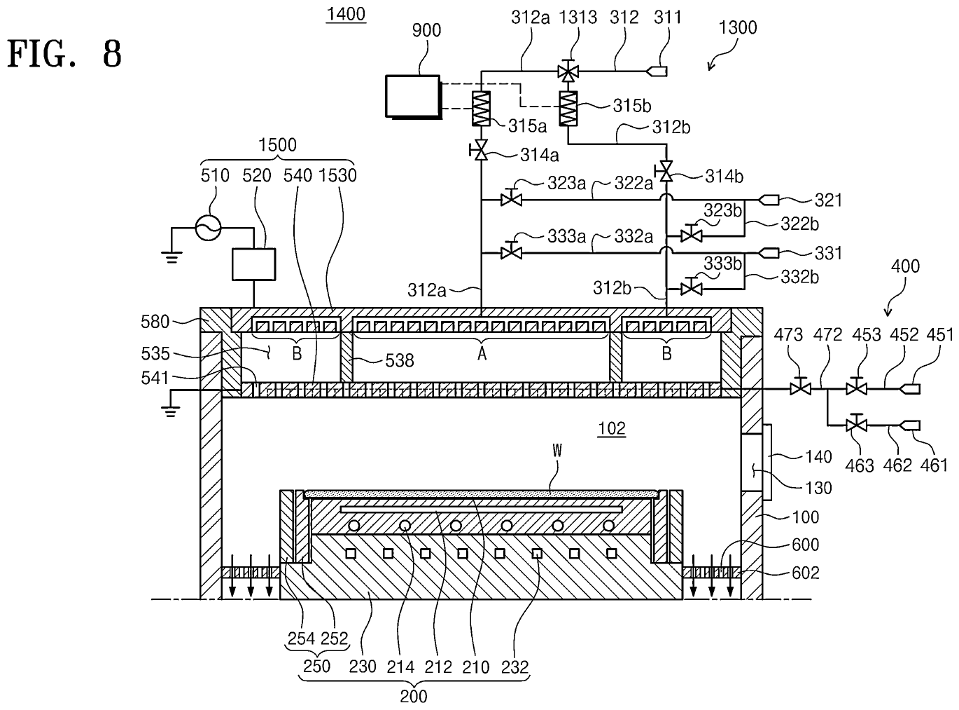

FIG. 8 is a schematic cross-sectional view of a substrate treating apparatus 1400 according to a fourth embodiment of the present disclosure. Hereinafter, the third embodiment will explain a configuration different from that of the first embodiment, and the same configuration as in the first embodiment will be replaced with that of the first embodiment. The same configuration as that of the first embodiment use the same drawing references.

The plasma generation space 535 may be divided into a first area A and a second area B by a partition wall 538. The partition wall 538 is provided as a dielectric material. As the partition wall 538 is provided, the plasma generation space 535 is physically separated, so that the plasma generation for each area can be more efficiently controlled.

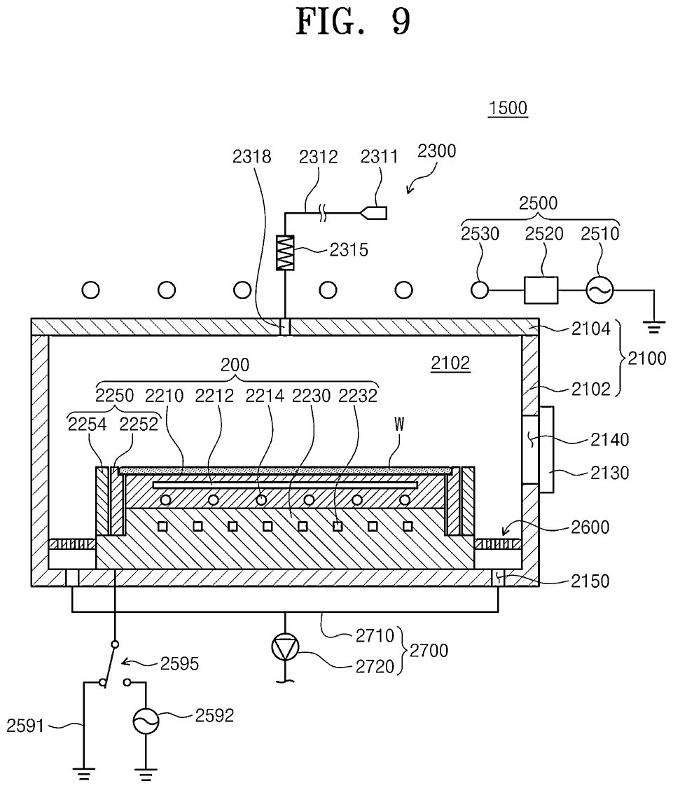

FIG. 9 is a schematic cross-sectional view of a substrate treating apparatus according to a fifth embodiment of the present disclosure.

The present disclosure may be applied to equipment that performs a process using plasma as in the illustrated embodiment. The substrate treating apparatus 1500 according to the fifth embodiment may include a process chamber 2100, a support unit 2200, a processing gas supply unit 2300, a plasma source 2500, and an exhaust unit 2700.

The process chamber 2100 provides an internal space as a processing space 2102. The support unit 2200 supports the substrate in the processing space 2102. The processing gas supply unit 2300 includes a heater 2315. The heater 2315 is installed on the gas supply line 2312, and the heater 2315 may be controlled to heat the processing gas supplied to the processing space 2102 to the temperature just before the temperature of the processing gas reaches its pyrolysis temperature. For example, the process gas may be sufficiently heated without being decomposed by the heat. The plasma source 2500 excites the processing gas supplied through the processing gas supply unit 2300 into a plasma state in the processing space 2102. The support unit 2200 may be selectively connected to ground line 2591 to be electrically grounded, or connected to a high frequency power source 2592 to receive high frequency power. When performing a high frequency power radical process, the unit is allowed to be connected to ground. And when performing an ion process, high frequency power can be applied. The exhaust unit 2700 may exhaust gas inside of the processing space 2102.

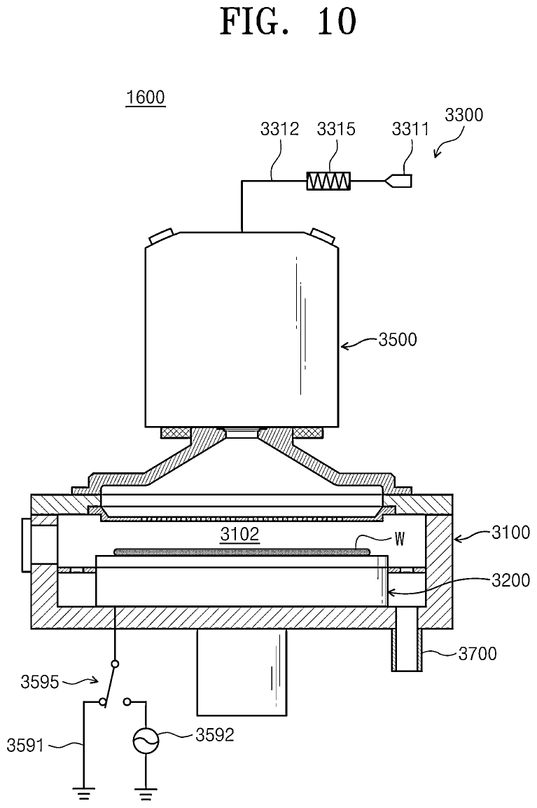

FIG. 10 is a schematic cross-sectional view of a substrate treating apparatus according to a sixth embodiment of the present disclosure.

The present disclosure can also be applied to the substrate treating apparatus 1600 using a remote plasma as in the sixth embodiment. The substrate treating apparatus 1600 may include a process chamber 3100, a support unit 3200, a processing gas supply unit 3300, a plasma generation unit 3500, and an exhaust unit 3700.

The process chamber 3100 has a processing space 3102 therein. The support unit 3200 supports the substrate W in the processing space 3102. The processing gas supply unit 3300 includes a heater 3315. The heater 3315 is installed on the gas supply line 3312, and the heater 3315 heats the processing gas supplied to the processing space 3102 just before the temperature of the processing gas reaches its pyrolysis temperature. For example, the process gas may be sufficiently heated without being decomposed by the heat. The plasma generation unit 3500 includes a plasma chamber (not shown) and a plasma source (not shown), and is provided upstream of the process chamber 3100. A plasma chamber (not shown) provides a space in which plasma is generated, and a plasma source (not shown) excites the processing gas supplied to the plasma chamber into a plasma state. The support unit 3200 may be selectively connected to ground line 3591 to be electrically grounded, or may be connected to a high frequency power source 3592 to receive high frequency power. When performing a high frequency power radical process, the unit is allowed to be connected to ground. And when performing an ion process, high frequency power can be applied. The exhaust unit 3700 may exhaust gas inside of the processing space 3102.

According to an embodiment of the present disclosure, in using plasma for substrate treating such as dry cleaning, particles generated from the plasma source generating components (including electrodes, showerheads, insulators, etc.) are prohibited and replacement cycle of the components may be extended by exciting the first processing gas heated to pre-pyrolysis level and by reducing the plasma energy required for generating radicals. Furthermore, the formation and suppression of plasma is rapidly controlled and a precise process is available by generating plasma with electric or electromagnetic plasma source.

Hereinabove, the controller 900 may control the entire operation of the substrate treating apparatuses 1000, 1100, 1200, 1300, 1400, 1500, and 1600 according to each embodiment. The controller 900 may include a central treating unit (CPU), a read only memory (ROM), and random-access memory (RAM). The CPU executes a treating such as etching treating according to various recipes stored in these storage areas.

The recipe includes process time, process pressure, high frequency power or voltage, various gas flow rates, temperatures inside of chamber (including temperature of electrode, temperature of chamber side wall, temperature of electrostatic chuck, etc.), temperature of cooler, etc. On the other hand, recipes indicating these programs and treating conditions may be stored in a non-transitory computer-readable medium. The non-transitory computer-readable medium refers to a medium that stores data semi-permanently and is computer-readable, rather than a medium that stores data for a short moment, such as registers, caches, and memory. Specifically, the various applications or programs described above may be provided by being stored in a non-transitory readable medium such as a CD, DVD, hard disk, Blu-ray disk, USB, memory card, ROM, or the like.

The detailed description hereinabove is illustrative of the present disclosure. Additionally, the description hereinabove is intended to illustrate and describe various embodiments for implementing the technical idea of the present disclosure, and the present disclosure may be used in various other combinations, modifications, and environments. That is, changes or modifications may be made within the scope of the concept of the disclosure disclosed herein, the scope equivalent to the disclosed contents, and/or the skill or knowledge of the art. Accordingly, the detailed description of the disclosure is not intended to limit the disclosure to the disclosed embodiment. Additionally, claims hereinafter should be construed as including other embodiments. Further, these variations should not be individually understood from the technical spirit or perspective of the present disclosure.

What is claimed is:

1. A method of treating a substrate, the method comprising:
supplying a first processing gas to a plasma generation space to generate plasma from the first processing gas; and
treating the substrate by supplying the plasma to the substrate, wherein the first processing gas is supplied to the plasma generation space after being heated.

2. The method of claim 1,
wherein the first processing gas is supplied to the plasma generation space after being heated to a pre-pyrolysis temperature of the first processing gas.

3. The method of claim 1,
wherein the first processing gas is supplied to different areas of the plasma generation space with different temperature.

4. The method of claim 3,
wherein the different areas comprise a first area corresponding to a central zone of the substrate, and a second area corresponding to an edge zone of the substrate.

5. The method of claim 4,
wherein a temperature of the first processing gas supplied to the first area is higher than a temperature of the first processing gas supplied to the second area.

6. The method of claim 1,
wherein the treating the substrate comprises removing a natural oxide layer from the substrate.

7. The method of claim 1,
wherein the first processing gas comprises a fluorine-containing gas.

8. A method of treating a substrate, comprising:
heating a first processing gas;
supplying the heated first processing gas to a plasma generation space and exciting the heated first processing gas into plasma by applying a high frequency to the plasma generation space;
providing radicals after filtering ions from the plasma which is excited from the plasma generation space to a processing space provided with the substrate;
obtaining a reactive gas by supplying a second processing gas to the processing space to react with the radicals; and
treating the substrate with the reactive gas.

9. The method of claim 8,
wherein the step of providing radicals after filtering ions from the plasma which is excited from the plasma generation space to a processing space provided with the substrate is performed by a showerhead having through holes formed between the plasma generation space and the processing space, and
wherein the showerhead is connected to ground.

10. The method of claim 8,
wherein the first processing gas is heated to a pre-pyrolysis temperature.

11. The method of claim 8,
wherein the first processing gas is supplied to different areas of the plasma generation space with different temperature.

12. The method of claim 11,
wherein the different areas comprise a first area corresponding to a central zone of the substrate, and a second area corresponding to an edge zone of the substrate.

13. The method of claim 12,
wherein a temperature of the first processing gas supplied to the first area is higher than a temperature of the first processing gas supplied to the second area.

14. The method of claim 8,
wherein the treating the substrate comprises removing a natural oxide layer from the substrate.

15. The method of claim 8,
wherein the first processing gas comprises a fluorine-containing gas.

16. The method of claim 8,
wherein the second processing gas comprises nitrogen- and hydrogen-containing gas.
